(19) United States
(12) Patent Application Publication
(10) Pub. No.: US 2025/0364309 A1
(43) Pub. Date: Nov. 27, 2025

(54) ISOLATION STRUCTURES IN TRANSISTOR DEVICES AND METHODS OF FORMING

(71) Applicant: Taiwan Semiconductor Manufacturing Co., Ltd., Hsinchu (TW)

(72) Inventors: Fang Hsuan Hu, Hsinchu (TW); Yen-Chun Huang, Taipei (TW); Zhen-Cheng Wu, Hsinchu (TW); Tze-Liang Lee, Hsinchu (TW)

(21) Appl. No.: 18/673,546

(22) Filed: May 24, 2024

(51) Int. Cl. H01L 21/762; H01L 29/06; H01L 29/423; H01L 29/66; H01L 29/775

(52) U.S. Cl. CPC H01L 21/76224; H10D 30/014; H10D 30/43; H10D 30/6735; H10D 62/121; H10D 64/017

(57) ABSTRACT

A device, includes a first semiconductor fin and a second semiconductor fin; an isolation structure between the first semiconductor fin and the second semiconductor fin, the isolation structure comprising: an inner shallow trench isolation (STI) region; a first liner layer along sidewalls and a bottom surface of the inner STI region; and a STI hard mask on a top surface of the inner STI region. The STI hard mask and the first liner layer each comprise a higher concentration of nitrogen than the inner STI region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6, 7, 8, 9, 10, 11, 12, 13A, 13B, 14A, 14B, 15A, 15B, 15C, 16A, 16B, 17A, 17B, 17C, 18A, 18B, 18C, 18D, 19A, 19B, 20A, 20B, 21A, 21B, 21C, 22A, 22B, 23A, 23B, 23C, 24A, 24B, 24C, 25A, 25B, and 25C illustrate varying views of intermediary steps of manufacturing a nano-FET transistor, in accordance with some embodiments.

FIGS. 26A, 26B, and 26C illustrate cross-sectional views of a nano-FET transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, isolation regions (e.g., shallow trench isolation (STI) regions) are formed between and around fins of a transistor to provide isolation between various active regions of the transistor and to isolate the transistor from other transistors in an integrated circuit die. Hard mask layers may be formed on a top surface of the isolation region to reduce isolation region loss during subsequent cleaning and/or etching processes that are performed to fabricate the transistor. The hard mask layers may include a nitride hard mask, and a silicon hard mask over the nitride hard mask. Due to the high etching selectivity of the silicon hard mask compared to even the nitride hard mask, the silicon hard mask may provide additional protection during the subsequent processing steps (e.g., etching steps). Thus, the combined thickness of the hard mask layers can be kept relatively low while still providing adequate protection to the underlying isolation region, and parasitic capacitance that result from overly thick hard mask layers can be reduced. The thinner hard mask layers further reduce the risk of unintentionally covering nanostructures of the transistor and impeding transistor performance. As a result, manufacturing defects can be reduced, and electrical performance of the resulting device can be improved.

Embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the nano-FETs.

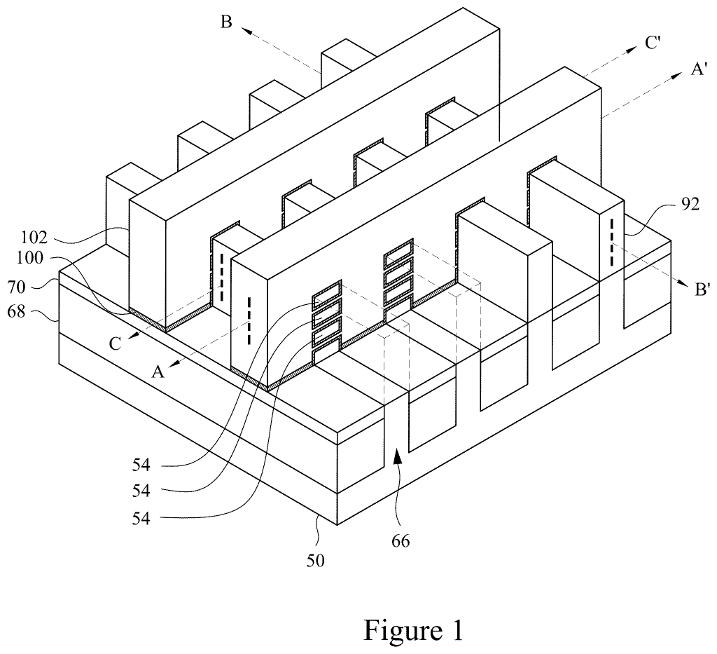

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Isolation structures 68 (also referred to as STI structures or STI regions) are disposed between adjacent fins 66, which may protrude above and from between neighboring isolation structures 68. A hard mask structure 70 is formed on a top surface of the isolation structure 68. In FIG. 1, the hard mask structure 70 is illustrated as a single layer. However, as will be described in subsequent paragraphs, in various embodiments, the hard mask structure 70 is a multi-layer structure comprising, for example, a nitride hard mask and a silicon hard mask over the nitride hard mask. Although the isolation structures 68 and the hard mask structure 70 are described/illustrated as being separate from the substrate 50, as used herein, the term “substrate” may refer to the semiconductor substrate alone or a combination of the semiconductor substrate and the isolation regions and/or the hard mask structure 70. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation structures 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

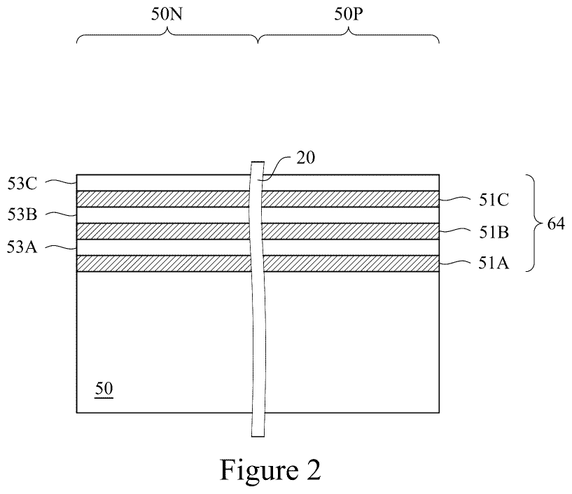

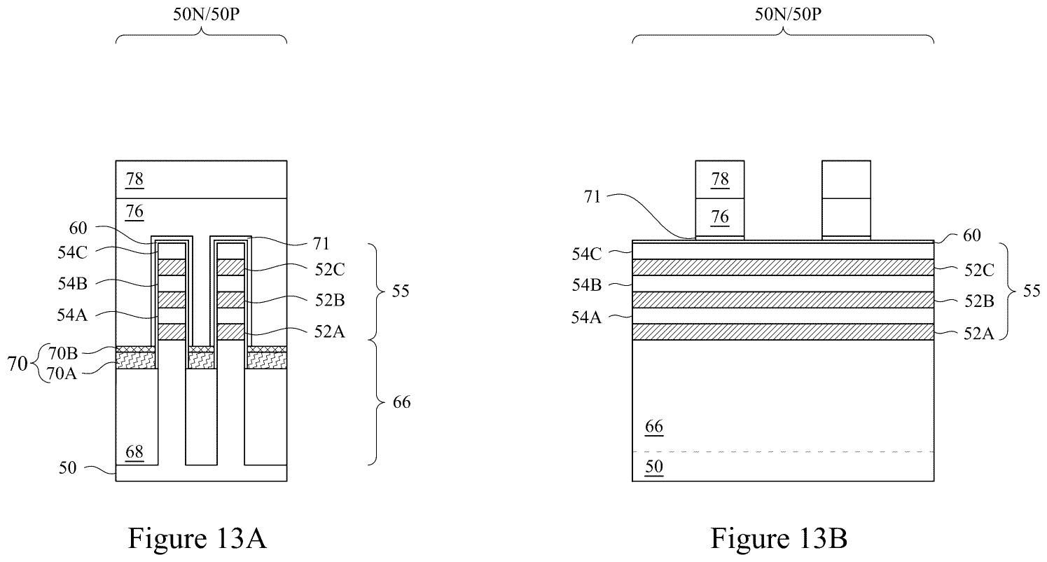

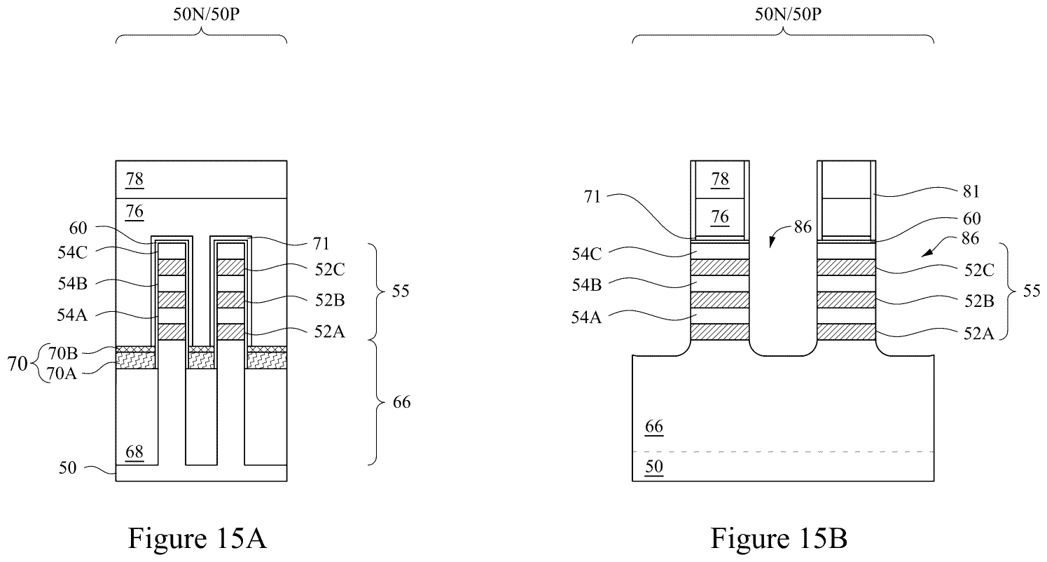

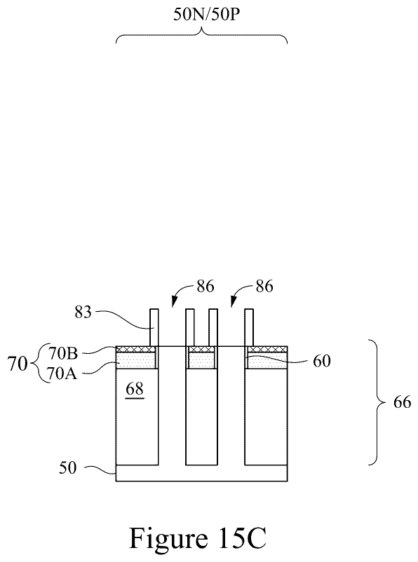

FIGS. 2 through 25C are cross-sectional views of intermediate stages in the manufacturing of nano-FETs, in accordance with some embodiments. FIGS. 2, 3, 4, 5, 6, 7, 8, 9, 10, 11, 12, 13A, 14A, 15A, 16A, 17A, 18A, 19A, 20A, 21A, 22A, 23A, 24A, and 25A illustrate reference cross-section A-A′ illustrated in FIG. 1. FIGS. 13B, 14B, 15B, 16B, 17B, 18B, 19B, 20B, 21B, 22B, 23B, 24B, and 25B illustrate reference cross-section B-B′ illustrated in FIG. 1. FIGS. 15C, 16C, 18C, 18D, 21C, 23C, 24C, and 25C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

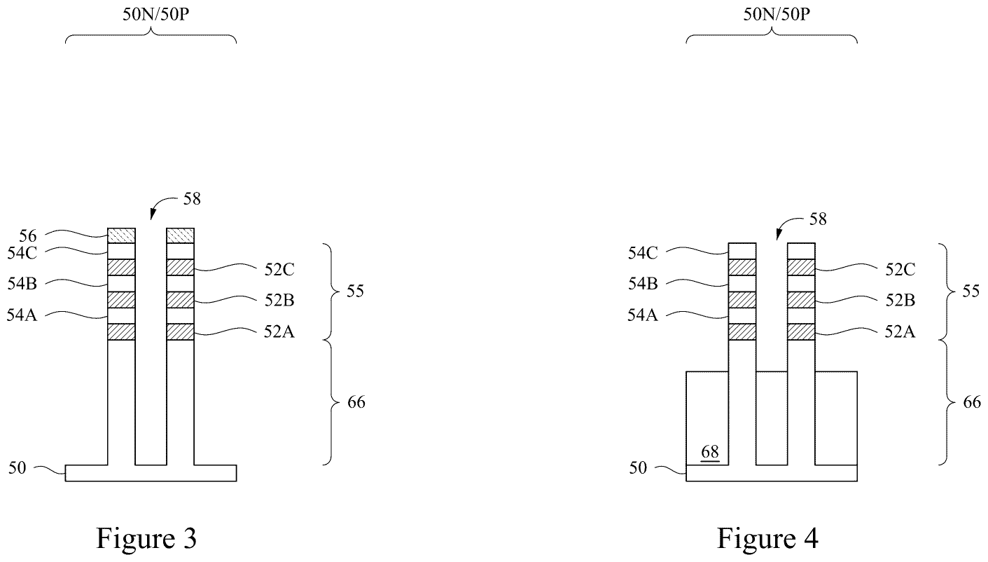

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape. Still further, a bottom surface of the trenches 58 between the fins 66 may be rounded and include concave and/or convex portions.

In FIG. 4, isolation structures 68 are formed in the trenches 58 and adjacent the fins 66. The isolation structures 68 may be formed by depositing layers of insulation material over the substrate 50, the fins 66, the nanostructures 55, and the hard masks 56, and then patterning the layers of insulation material below the nanostructures 55. Forming the isolation structures 68 may include depositing an insulation material over the substrate 50 and between the semiconductor fins 66 and the nanostructures 55. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. The insulation material may be formed of a carbon-free dielectric material. In some embodiments, the insulation material includes silicon oxide formed by an FCVD process. An annealing process may be performed once the insulation material is formed. Although the insulation material in FIG. 3 is illustrated as a single layer, some embodiments may utilize multiple layers. For example, in some embodiments one or more liners (not separately illustrated) may first be formed along a surface of the substrate 50, the semiconductor fins 66, and the nanostructures 55. Thereafter, a fill material, such as one of the previously described insulation materials may be formed over the liner(s).

The insulation material may be deposited over the semiconductor fins 66 and nanostructures 55 such that excess insulation material covers the nanostructures 55 and optionally the hard mask 56. A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are substantially coplanar (within process variations) after the planarization process is complete. The planarization process may also remove the hard mask 56. Alternatively, the hard mask 56 may be removed in a separate etching process prior to depositing the insulation material.

After the planarization process, the insulation material is recessed to form isolation structures 68 (also referred to as isolation regions or shallow trench isolation (STI) regions). The isolation structures 68 are adjacent the semiconductor fins 66. The isolation structures 68 is recessed such that upper portions of the semiconductor fins 66 and the nanostructures 55 protrude from between neighboring isolation structures 68. The upper portions of the semiconductor fins 66 and the nanostructures 55 are above the isolation structures 68. Further, the top surfaces of the isolation structures 68 may have a flat surface as illustrated, a convex surface, a concave surface (such as dishing), or a combination thereof. The top surfaces of the isolation structures 68 may be formed flat, convex, and/or concave by an appropriate etch. The isolation structures 68 may be recessed using any acceptable etching process, such as one that is selective to the material of the insulation material (e.g., selectively etches the isolation material of the isolation structures 68 at a faster rate than the materials of the semiconductor fins 66 and the nanostructures 55). For example, an oxide removal process using, for example, dilute hydrofluoric (dHF) acid may be used. In some embodiments, the etching is anisotropic.

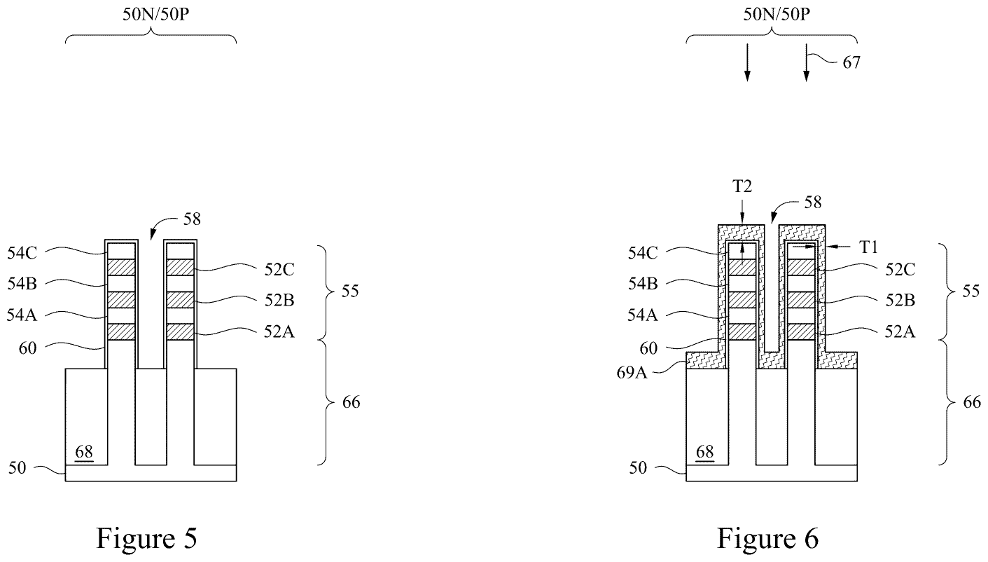

In FIG. 5, an optional protective liner 60 is deposited over and along sidewalls of the nanostructures 55 and on exposed upper sidewalls of the fins 66. In some embodiments, the protective liner 60 is made by growing a silicon layer using an epitaxial process, such as, CVD, ALD, VPE, MBE, or the like. In some embodiments, the protective liner 60 is selectively deposited on a semiconductor material of the nanostructures 55 and the fin 66 without being deposited on the exposed, surfaces of the isolation structures 68. The deposition process used to form the protective liner 60 may allow a relatively high-quality material to be formed. For example, when the protective liner 60 is a silicon layer that is deposited by an ALD process, the protective liner 60 may have improved coverage and be more crystalline than the second nanostructures 54. The higher quality material of the protective liner 60 may be more resistant to etching and reduce undesired thinning of the second nanostructures 54 during subsequent processing steps. As a result, the protective liner 60 may allow for higher quality channel regions to be formed in the resulting device. The protective liner 60 may be omitted in some embodiments.

In FIG. 6, a first liner material 69A is deposited over and along sidewalls of the nanostructures 55, on the upper sidewalls of the fins 66, and on the upper surfaces of the isolation structures 68. The first liner material 69A may be deposited over the protective liner 60 in embodiments where the protective liner 60 is present. The first liner material 69A may be a nitride layer, such as a silicon nitride layer, a silicon oxynitride layer, a silicon oxycarbonitride layer, or the like. A nitrogen concentration of the first liner material 69A may be greater than a nitrogen concentration of the isolation structure 68. In some embodiments, the first liner material 69A has a ratio of nitrogen to silicon in a range of 0.7 to 1.5. It has been observed that when the ratio of nitrogen to silicon of the first liner material 69A is in the above range, adequate protection can be provided to the underlying isolation structures 68 to prevent undue isolation structure loss in subsequent process steps (e.g., subsequent etching steps). In some embodiments, the first liner material 69A has a ratio of carbon to silicon that is less than 0.1, and the first liner material 69A has a ratio of oxygen to silicon that is less than 0.1.

In some embodiments, the first liner material 69A is deposited by a non-conformal deposition process, such as, a plasma enhanced CVD (PECVD) process or the like. The non-conformal deposition process may form sidewalls portions of the first liner material 69A to have a thickness T1 that is less a thickness T2 of lateral portions of first liner material 69A. The non-conformal deposition process may aid in the patterning and selective removal of the sidewall portions of the first liner material 69A as will be discussed in greater detail subsequently.

In some embodiments, the non-conformal deposition process is a PECVD process. The PECVD process may be performed at a temperature in a range of 400° C. to 500° C. During the PECVD process, a silicon-based precursor and H₂ gas may be flowed into the chamber to form a silicon-based material layer (e.g., a silicon layer) over and along sidewalls of the fins 66 and the nanostructures 55. Subsequently to or concurrently with depositing silicon-based material layer, a plasma treatment may be applied to treat the silicon-based material layer with a nitrogen-containing radical, thereby forming the first liner material 69A. The plasma treatment may be applied in a direction that is substantially perpendicular to a top surface of the substrate 50 as indicated by the arrows 67. The directionality of the plasma treatment results in the difference of thicknesses T1 and T2 between the sidewall portions and the lateral portions of the first liner material 69A, respectively. Further, the directionality of the plasma treatment may result in improved film quality (e.g., increased nitrogen uniformity) in the lateral portions of the first liner material 69A compared to the sidewall portions of the first liner material 69A.

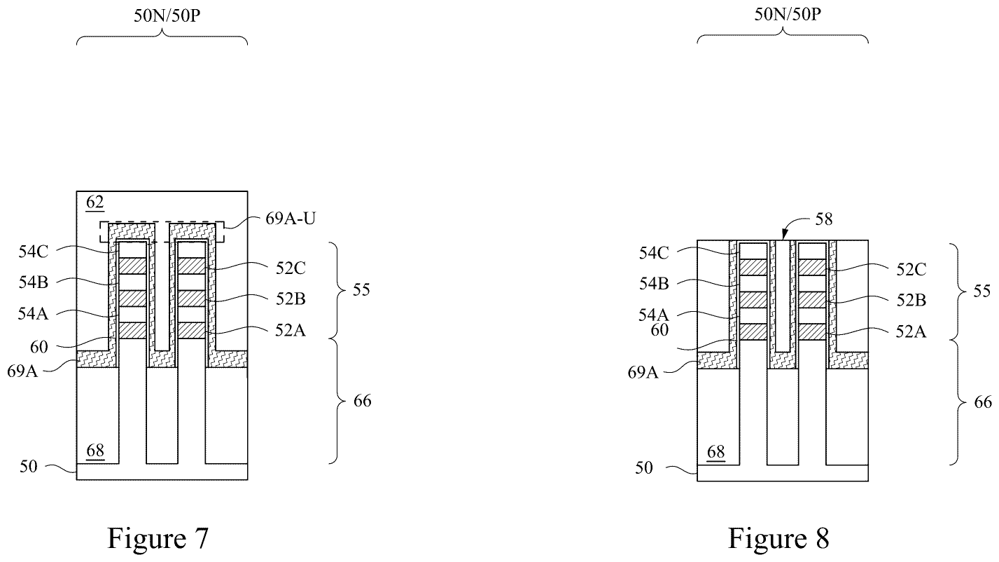

In FIGS. 7 and 8, upper portions 69A-U of the first liner material 69A are removed. The upper portions 69A-U of the first liner material 69A may include lateral portions of the first liner material 69A that are disposed above the nanostructures 55. Removing the upper portions 69A-U of the first liner material 69A may include depositing a mask layer 62 over the first liner material 69A as illustrated by FIG. 7. The mask layer 62 may extend over the nanostructures 55. In some embodiments, the mask layer 62 is a backside anti-reflective coating (BARC) layer that is deposited by PVD or the like. Other materials and/or deposition processes are possible in other embodiments.

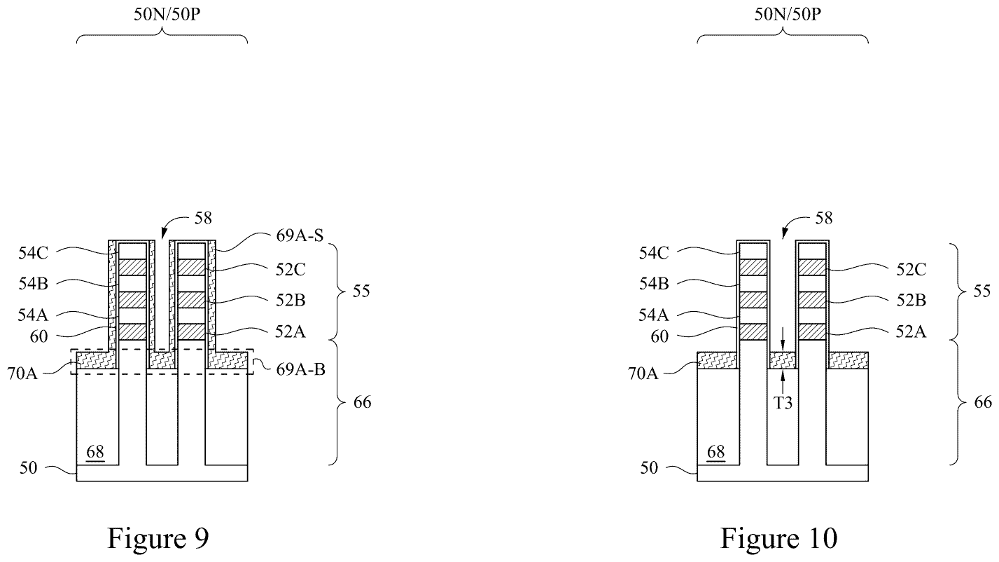

Subsequently, in FIG. 8, one or more etching processes may be performed to remove the upper portions 69A-U of the first liner material 69A. For example, an etch back process may be applied to the mask layer 62 to expose the upper portions 69A-U of the first liner material 69A. Then, the upper portions 69A-U of the first liner material 69A may be etched away by an anisotropic etching process, for example. Remaining portions of the mask layer 62 protects sidewall and bottom portions of the first liner material 69A while the upper portions 69A-U of the first liner material 69A are removed. After the upper portions 69A-U are removed, the remaining mask layer 62 may also be removed using a suitable etching and/or cleaning process. The resulting structure is illustrated in FIG. 9.

In FIG. 10, sidewall portions 69A-S (see FIG. 9) are then removed from the sidewalls of the nanostructures 55 and the fins 66 while bottom portions 69A-B remain on the top surfaces of the isolation structures 68. Removing the sidewall portions 69A-S may include an etching process, such as an isotropic etching process. some embodiments, the isotropic etching process is a wet etch using HPO₃ or the like as an etchant. As discussed above, the sidewall portions 69A-S are formed to be thinner than the bottom portions 69A-B as a result of the non-conformal deposition process (e.g., PECVD) used to deposit the first liner material 69A. The relative thinness of the sidewall portions 69A-S compared to the bottom portions 69A-B allow for the sidewall portions 69A-S to be completely removed prior to completely removing the bottom portions 69A-B when an isotropic etching process is applied. As a result, the non-conformal deposition process described above allows the first liner material 69A to be selectively etched away from the sidewalls of the nanostructures 55 and the fins 66 while still leaving the bottom, lateral portions of the first liner material 69A to cover the isolation structures 68.

After the sidewall portions 69A-S are removed, the remaining first liner material 69A may be referred to as a first hard mask 70A (also referred to as an isolation hard mask or an STI hard mask). The first hard mask 70A is formed on lateral surfaces at the bottom of the trenches 58 over the protective liner 60 (if present) and the isolation structures 68. The first hard mask 70A may be formed to have a thickness T3 in a range of 1 nm to 10 nm to adequately protect isolation structures 68 during subsequent manufacturing processes. Further, a top surface of the first hard mask 70A may be below a top surface of the fins 66 and a bottommost nanostructure 55 (e.g., the nanostructure 52A) so as not to impede the removal of the first nanostructures 52 in subsequent process steps.

In FIG. 11, a second liner material 69B is deposited in the trenches 58 and over the first hard mask 70A. The second liner material 69B may be deposited over top surfaces of the nanostructures 55, along sidewalls of the nanostructures 55, and over upper surfaces of the isolation structures 68. The second liner material 69B may be formed of a material with a higher etch selectivity to the isolation structures 68 than the first hard mask 70A relative a same etch process. In some embodiments, the second liner material 69B is a semiconductor material. For example, the second liner material 69B may be made of silicon, or the like when the first hard mask 70A is made of a nitride material and the isolation structures 68 are made of an oxide material.

The second liner material 69B may be formed of a non-conformal deposition process, such as an FCVD process. An annealing process may be performed once the second liner material 69B is formed. As a result of the FCVD process, the second liner material 69B may tend to accumulate on lateral surfaces at the bottom of the trenches 58 compared to sidewalls of the nanostructures 55 or top surfaces of the nanostructures 55. For example, a thickness T4 of the second liner material 69B along bottom surfaces of the trenches 58 may be greater than a thickness T5 of sidewall portions of the second liner material 69B and a thickness T6 of the second liner material 69B on top surfaces of the nanostructures 55. In some embodiments, the thickness T6 of the second liner material 69B on top surfaces of the nanostructures 55 may also be greater than the thickness T5 of the sidewall portions of the second liner material 69B. Further, the non-conformal deposition process may deposit a lower quality material than the material of the protective liner 60. For example, compared to the protective liner 60, the second liner material 69B may have worse coverage, particularly on sidewalls and upper surfaces of the nanostructures 55, as well as be less crystalline. As a result, the second liner material 69B may be more readily etched away in subsequent processes than the protective liner 60. Other non-conformal deposition processes, such as a PECVD process, may be used in other embodiments to deposit the second liner material 69B.

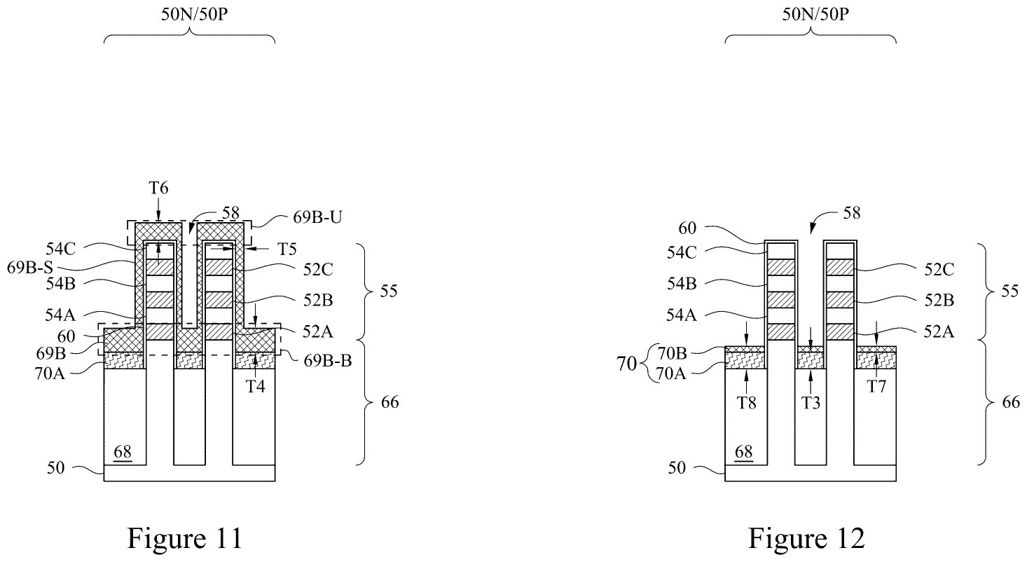

In FIG. 12, sidewall portions 69B-S and upper portions 69B-U of the second liner material 69B are removed while bottom portions 69B-B of the second liner material 69B remains (see FIG. 11). Similar to the first liner material 69A, the non-conformal deposition process allows for the sidewall portions 69B-S and upper portions 69B-U of the second liner material 69B to be selectively removed without completely removing the bottom portions 69B-B of the second liner material 69B. Removing the sidewall portions 69B-S and the upper portions 69B-U of the second liner material 69B may include an etching process, such as an isotropic etching process. In some embodiments, the isotropic etching process is a multistage process that includes exposing the second liner material 69 to a solution of hydrofluoric acid (HF) and ozonized deionized water (DIW), which may begin etching the second liner material 69B and further oxidize the second liner material 69B. The isotropic etching process may then continue by applying a standard clean 1 (SC1) process to remove the oxidized second liner material 69. Other etchants or etching process(es) may be used in other embodiments. As discussed above, the sidewall portions 69B-S and the upper portions 69B-U of the second liner material 69B are formed to be thinner than the bottom portions 69B-B of the second liner material 69B as a result of the non-conformal deposition process (e.g., FCVD) used to deposit the second liner material 69B. The relative thinness of the sidewall portions 69B-S and the upper portions 69B-U compared to the bottom portions 69B-B allow for the sidewall portions 69A-S to be completely removed prior to completely removing the bottom portions 69B-B when an isotropic etching process is applied. As a result, the non-conformal deposition process described above allows the second liner material 69B to be selectively etched away from the sidewalls and top surfaces of the nanostructures 55 and the fins 66 while still leaving the bottom, lateral portions of the second liner material 69B to cover the isolation structures 68 and the first hard mask 70A.

The protective liner 60 is more resistant to etching than the second liner material 69B even when the protective liner 60 and the second liner material 69B are made of a similar material (e.g., both silicon) due to the improved film quality of the protective liner 60 compared to the second liner material 69B. The differences in film quality may be attributed to differences in the deposition processes used to form the protective liner 60 (e.g., ALD) and the second liner material 69B (e.g., FCVD). Various embodiments may remove the sidewall portions 69B-S of the second liner material 69B without removing the protective liner 60.

In some embodiments, etching the second liner material 69B may thin (e.g., reduce a thickness) of the bottom portions 69B-B of the second liner material 69B. For example, after etching, the bottom portions 69B-B of the second liner material 69B may have thickness T7 that is less than the thickness T6 of the bottom portions 69B-B of the second liner material 69B prior to etching (see FIG. 11). In some embodiments, the thickness T7 may be in a range of 1 nm to 10 nm.

After the second liner material 69B is patterned, the remaining second liner material 69B may also be referred to as a second hard mask 70B (also referred to as an isolation hard mask or an STI hard mask). The second hard mask 70B is formed on lateral surfaces at the bottom of the trenches 58 over first hard mask 70A, the protective liner 60 (if present), and the isolation structures 68. The second liner material 69B may be thinned such that a top surface of the resulting, second hard mask 70B is below a bottommost surface of the nanostructures 55 (e.g., below the bottommost nanostructure 5A). As a result, the nanostructures 55 are fully exposed to subsequent processing steps, which allows for smooth integration of various isolation hard masks (e.g., the first and second hard masks 70A and 70B) into the transistor manufacturing process. The second hard mask 70B has a thickness of 1 nm to 10 nm. Forming the second hard mask 70B to have a thickness within the above range has advantages. For example, when the thickness of the second hard mask 70B is less than 1 nm, it may not adequately protect the underlying first hard mask 70A and the isolation structure 68 during subsequent processing. Further, when the thickness of the second hard mask 70B is greater than 10 nm, it may interfere with subsequent processing steps (e.g., by covering one or more of the nanostructures 55). Further, when the thickness of the second hard mask 70B is greater than 10 nm, parasitic capacitance due to the semiconductor material of the second hard mask 70B in the resulting transistor device may be unacceptably high.

Thus, hard mask structures 70 are formed. The isolation hard mask structure 70 has a multi-layer structure that comprises the first hard mask 70A (e.g., a nitride) and the second hard mask 70B (e.g., a silicon hard mask). In some embodiments, a native oxide may be formed in an upper region of the second hard mask 70B once the second hard mask 70B is exposed to ambient oxygen. Various embodiments contemplate the second hard mask 70B as being inclusive of this native oxide layer. The hard mask structure 70 protects the underlying isolation structure 68 during subsequent processing steps (e.g., subsequent etching and/or cleaning processes). In some embodiments, the isolation hard mask structure 70 has a thickness T8, which is the combined thickness of the thickness T3 of the first hard mask 70A and the thickness T7 of the second hard mask 70B. In various embodiments, by including the second hard mask 70B over the first hard mask 70A, the overall thickness of the hard mask structure 70 can be kept at an acceptably low value so as not to impede subsequent fabrication steps by, for example, covering the sidewalls of the bottom nanostructures 55. Further, by including a combination of materials in the first hard mask 70A and the second hard mask 70B, parasitic capacitance in the resulting device can be reduced.

The material(s) of the first and second hard masks 70A and 70B may be selected to have high-etch selectivity to the material of the isolation structure 68 relative a same etching process. For example, the material(s) of the first and second hard masks 70A and 80B may be selected to be resistant to etchants that etch the material of the isolation structure 68, one or more etchants may etch the material(s) of the first and second hard masks 70A and 70B at a slower rate than the isolation structure 68. In some embodiments, the second hard mask 70B may have even greater etch selectivity than the first hard mask 70A to the isolation structure 68 relative a same etch process. In some embodiments, the isolation structures 68 is an oxide layer, the first hard mask 70A comprises a nitride material, and the second hard mask 70B is a semiconductor material (e.g., silicon). As a result, undue loss of the isolation structure 68 can be avoided, manufacturing defects can be reduced, and device performance can improve.

Further in FIG. 12, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 13A and 13B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 71 is shown covering only the fins 66 and the nanostructures 55 for illustrative purposes only. In some embodiments, the dummy gate dielectrics 71 may be deposited such that the dummy gate dielectrics 71 covers the isolation structures 68 and the hard mask structures 70, such that the dummy gate dielectrics 71 extends between the dummy gates 76 and the isolation structures 68.

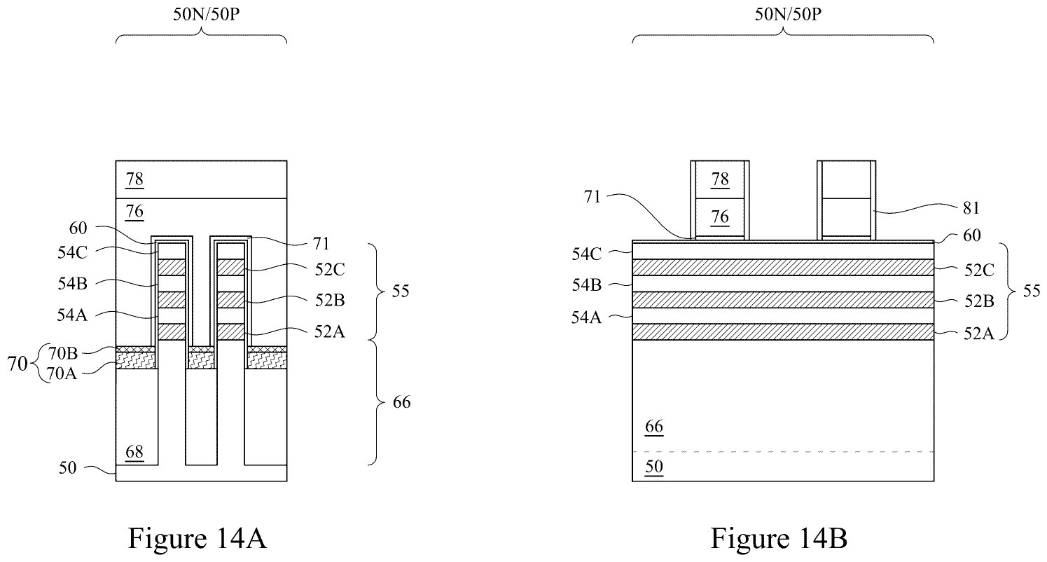

In FIGS. 14A and 14B, gate spacers 81 are formed over the nanostructures 55 and the isolation structures 68 (e.g., over the hard mask structures 70), on exposed sidewalls of the masks 78 (if present), the dummy gates 76, and the dummy dielectrics 71. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 15C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 15A-15C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 15C, top surfaces of the hard mask structure 70 (e.g., a top surface of the second hard mask 70B) may be level with bottom surfaces of the first recesses 86. In various embodiments, the fins 66 may be etched such that bottom surfaces of the first recesses 86 are disposed below the top surfaces of the hard mask structures 70; or the like. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

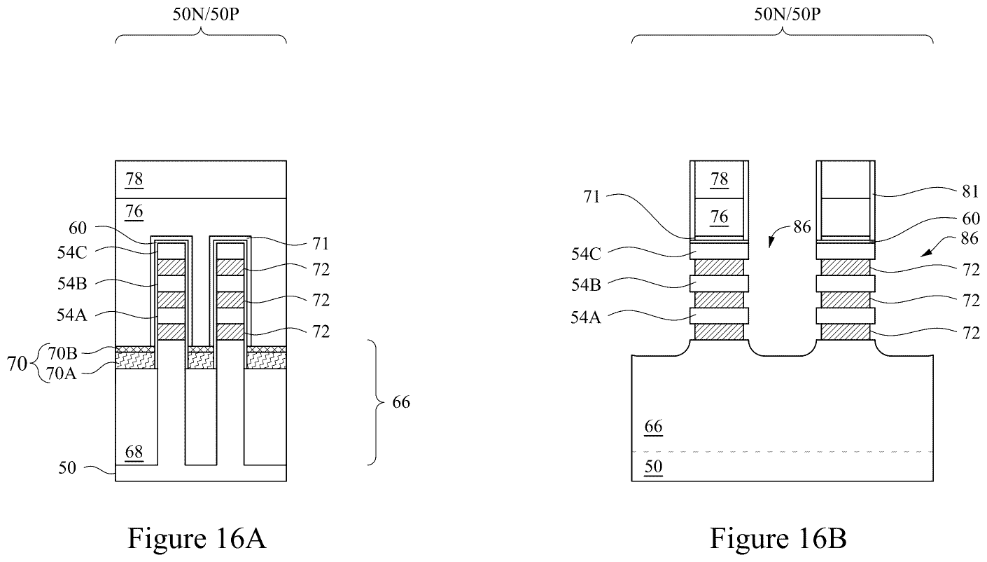

In FIGS. 16A and 16B, the first nanostructures 52 are replaced with a sacrificial material 72. Replacing the first nanostructures 52 may include etching away the first nanostructures 52 using a suitable etch process, such as an isotropic etch process, that is performed through the first recesses 86. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

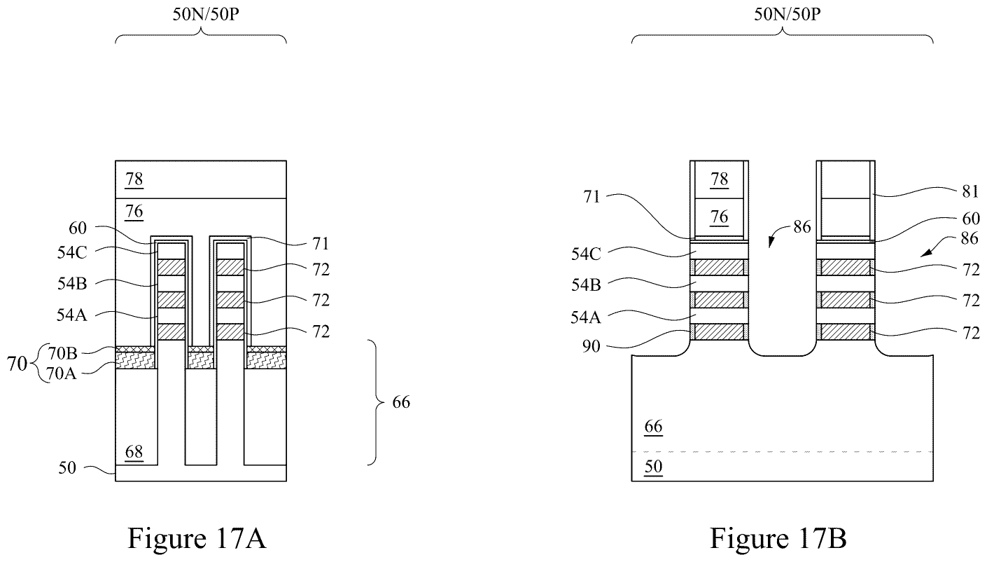

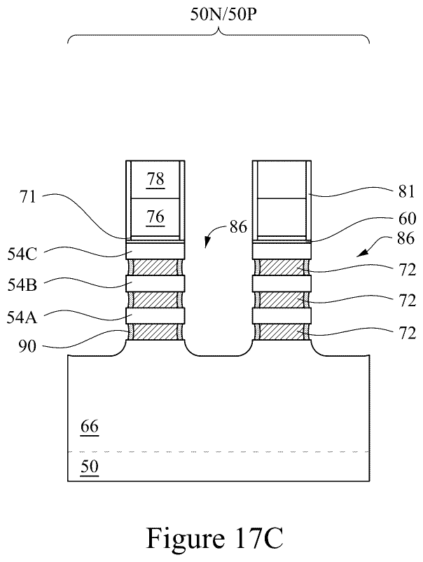

Subsequently, a sacrificial material layer is deposited in the recesses 86 and spaces where the first nanostructures 52 were removed. The sacrificial material layer may be deposited by a conformal deposition process, such as CVD, ALD, or the like. The sacrificial material layer may comprise an insulating material such as silicon oxide (e.g., SiO₂), or the like. The sacrificial material layer may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 16B, the sidewalls may be concave or convex (see e.g., FIG. 17C). The hard mask structures 70 protect the isolation structures 68 during the etching of the sacrificial material layer. In some embodiments, the material of the second hard mask 70B (e.g., silicon) is more resistant (e.g., has higher etch selectivity) to etching during the patterning of the sacrificial material layer than the material of the first hard mask 70A (e.g., nitride). As a result, by including the second hard mask 70B, improved protection for the underlying isolation structures 68 can be achieved without significantly increasing an overall thickness of the hard mask structures 70.

Replacing the first nanostructures 52 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. By replacing the first nanostructures 52 with an insulating material prior to the high temperature processes (e.g., source/drain annealing), manufacturing defects can be reduced and device performance can be improved.

In FIGS. 17A and 17B, inner spacers 90 are formed in the recesses 86 on the sidewalls of the sacrificial material 72. The inner spacers 90 may be formed by depositing an inner spacer layer (not separately illustrated) over the structures illustrated in FIGS. 16A and 16B. The inner spacers 90 act as isolation features between subsequently formed source/drain regions and a gate structure. As will be discussed in greater detail below, source/drain regions will be formed in the recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 17C).

Moreover, although the outer sidewalls of the inner spacers 90 are illustrated as being straight in FIG. 17B, the outer sidewalls of the inner spacers 90 may be concave or convex. As an example, FIG. 17C illustrates an embodiment in which sidewalls of the sacrificial material 72 are concave, outer sidewalls of the inner spacers 90 are concave, and the inner spacers 90 are recessed from sidewalls of the second nanostructures 54. The inner spacer layer may be etched by an anisotropic etching process, such as RIE, NBE, or the like.

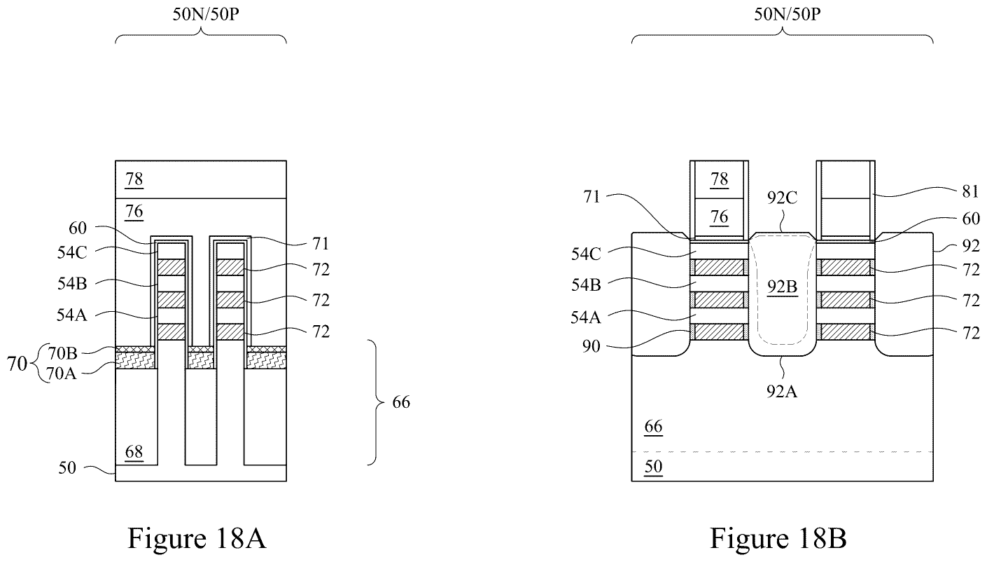

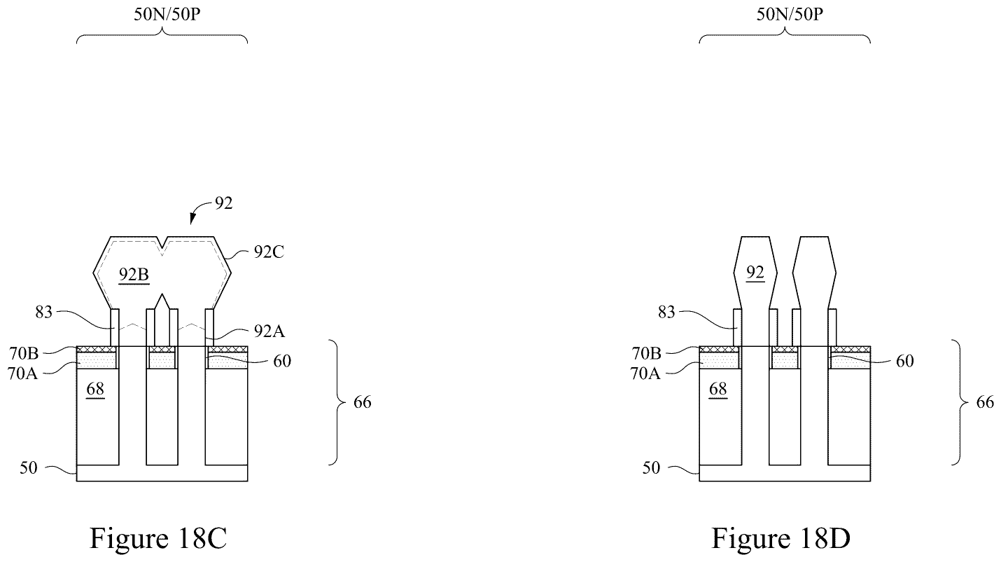

In FIGS. 18A-18D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 18B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a comprissive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed.

In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 18C. In other embodiments, adjacent epitaxial source/drain regions 92 remain separated after the epitaxy process is completed as illustrated by FIG. 18D. In the embodiments illustrated in FIGS. 18C and 18D, the fin spacers 83 may be formed to a top surface of the hard mask structures 70, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

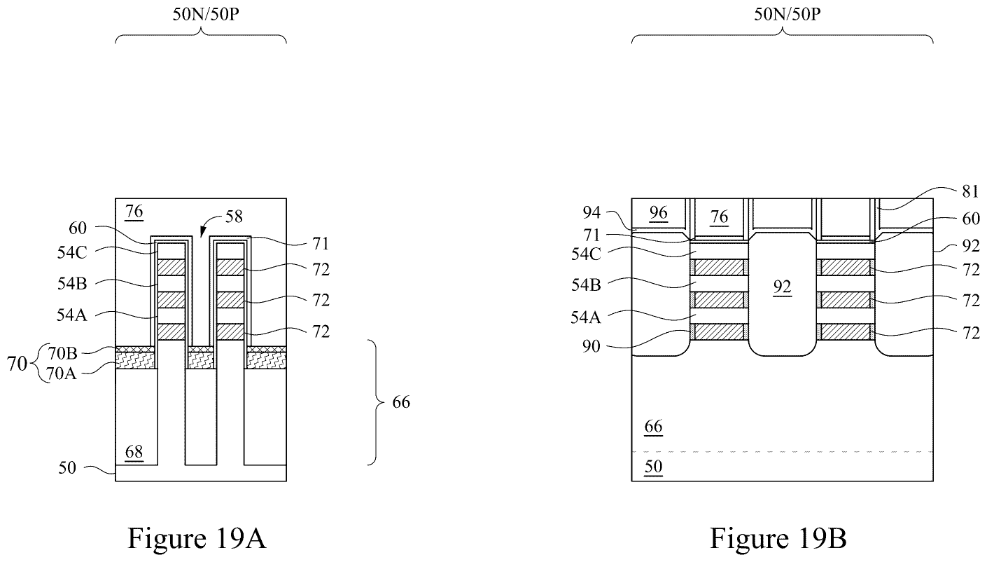

In FIGS. 19A and 19B, a first interlayer dielectric (ILD) 96 is deposited over the structure illustrated in FIGS. 18A and 19B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

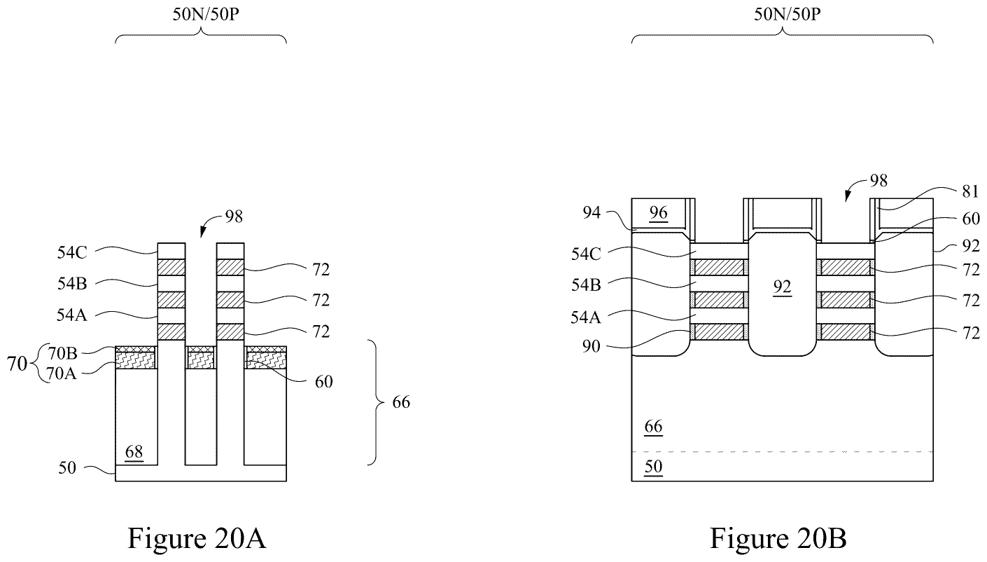

In FIGS. 20A and 20B, the dummy gates 76, and the masks 78 if present, are removed in one or more etching steps, so that second recesses 98 are formed. Portions of the dummy gate dielectrics 71 and portions of the protective liner 60 in the second recesses 98 may also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

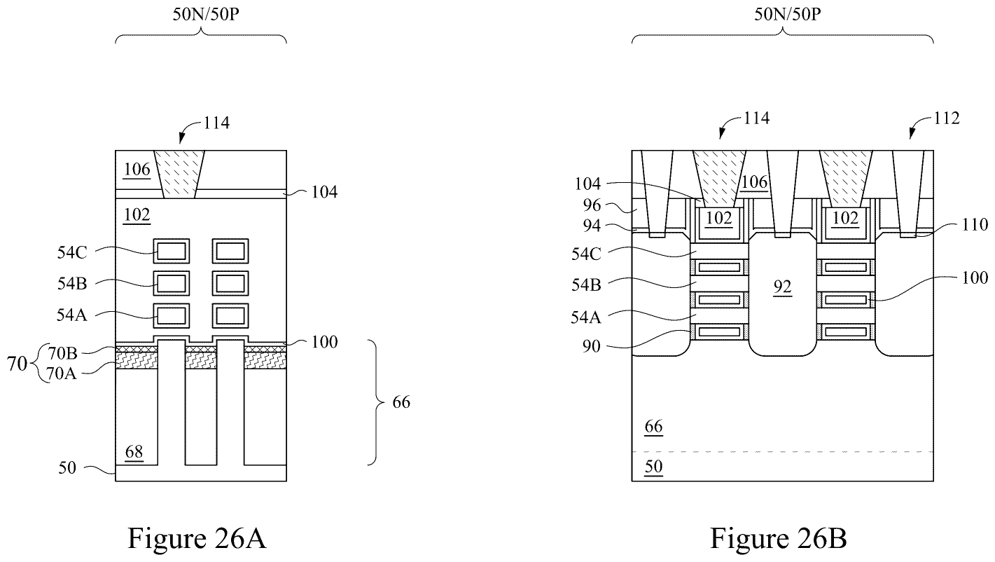

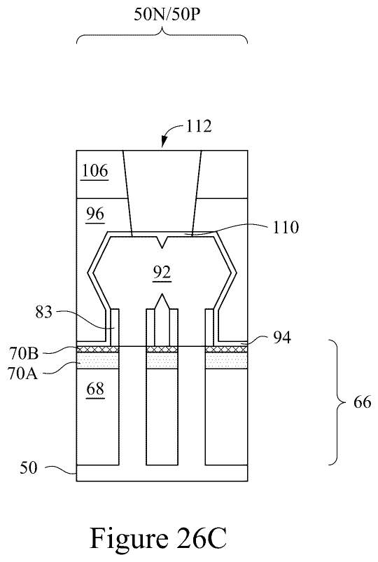

Portions of the protective liner 60 in the second recesses 98 may then be removed. Removing the protective liner 60 may include any suitable etching process. The etching may be isotropic. In some embodiments, due to the similarity of the materials of the protective liner 60 and the second hard mask 70B, removing the protective liner 60 may include thinning the second hard mask 70B. However, because protective liner 60 is formed to be thinner than the second hard mask 70B, timing can be controlled such that the protective liner 60 is removed without completely removing the second hard mask 70B. In some embodiments, portions of the protective liner 60 remain on sidewalls of the fins 66, such as portions of the protective liner 60 that are covered by the hard mask structure 70. In other embodiments, the protective liner 60 is completely removed, even from the fins 66 (see e.g., FIGS. 26A-26C).

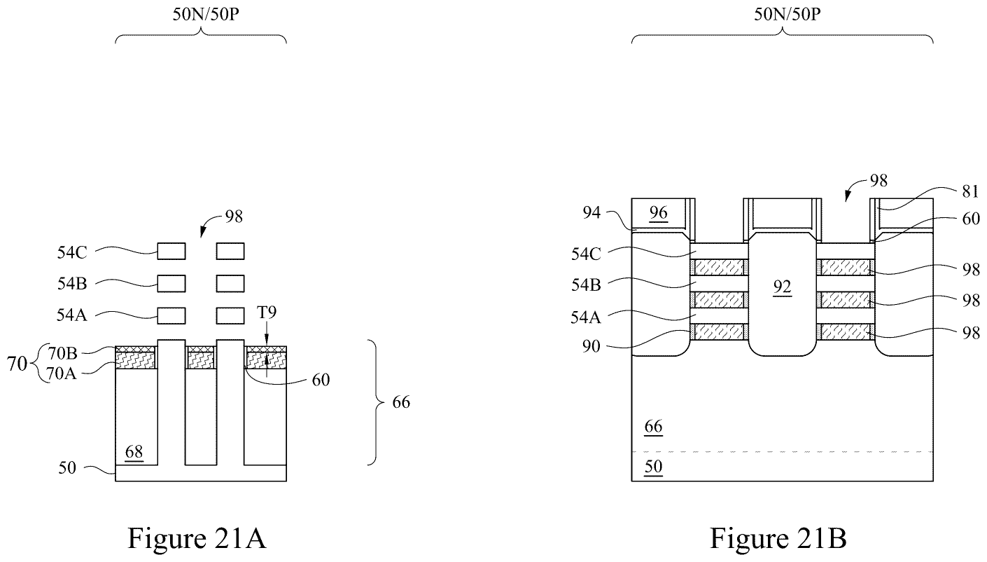

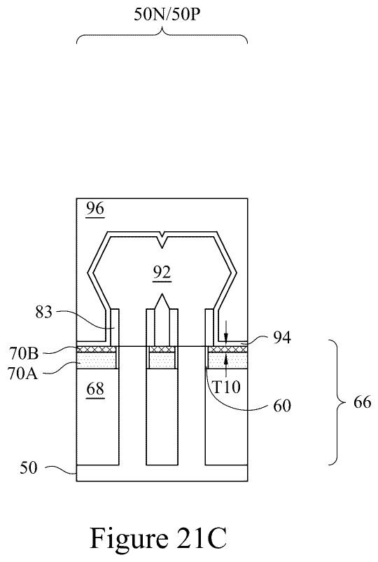

In FIGS. 21A-21C, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54, the substrate 50, and hard mask structure 70 remain relatively unetched as compared to the sacrificial material 72.

In various embodiments, the isolation structures 68 in both the n-type region 50N and the p-type region 50P are relatively unetched due to the hard mask structures 70, particularly the second hard mask 70B providing increased etch resistivity, particularly during the patterning and the removal of the sacrificial material 72. For example, in the process steps described above, the hard mask structures 70 may be exposed to one or more etchants that etches the isolation structures 68 at a greater rate than each of the first and second hard masks 70A and 70B. While the etchants may still reduce an overall thickness of the hard mask structures 70 (e.g., reduce an overall thickness of the second hard mask 70B), STI loss kept at an acceptably low amount. For example, a thickness of the second hard mask 70B may be reduced from an original thickness T8 to a thickness T9 in the second recesses 98. Loss of the hard mask structure 70 may be relatively minimal due to the high etch selectivity provided by the material of the second hard mask 70B, thereby leaving adequate isolation in the resulting transistors devices and improving device performance. In some embodiments, the original thickness T9 of the second hard mask 70B may be in a range of 1 nm to 10 nm, and the thickness T9 of the second hard mask 70B after additional processing may be less than 5 nm, for example. Further, as illustrated by FIG. 21C, portions of the hard mask structures 70 may be covered by the CESL 94 and the first ILD 96 during some of the processing described above (e.g., during the removal of the dummy gates 76, the dummy gate dielectrics 71, and select nanostructures 55). As such, these covered portions of the hard mask structures 70 that directly underlie the first ILD 96 may be etched less than exposed portions of the hard mask structures 70 (see FIG. 21A). For example, the covered portions of the second hard mask 70B may have a thickness T10 (see FIG. 21C) that is different from (e.g., greater than) the thickness T9 of the exposed portions of the second hard mask 70B (see FIG. 21A). In some embodiments, the thickness T10 may also be less than the original thickness T8.

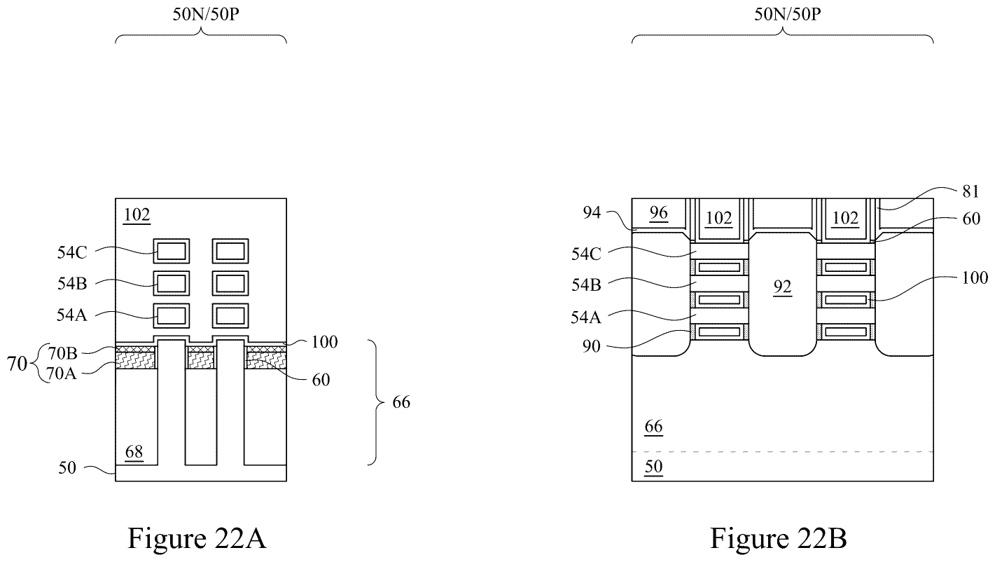

In FIGS. 22A and 22B, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the hard mask structures 70.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 22A and 22B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

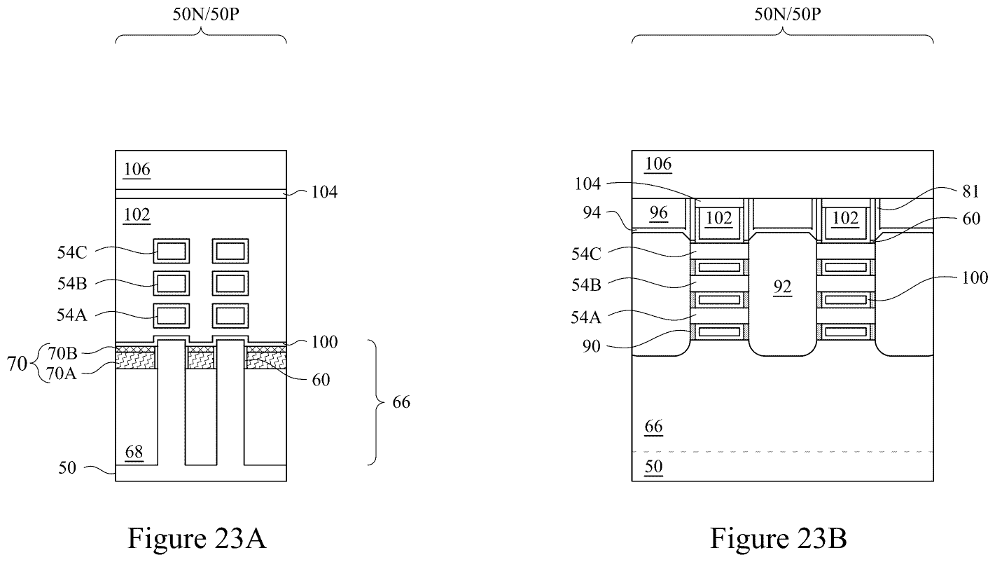

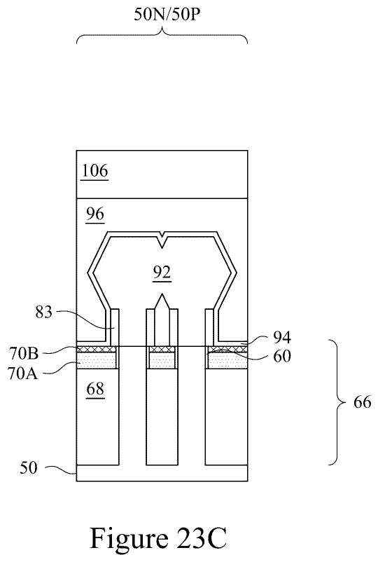

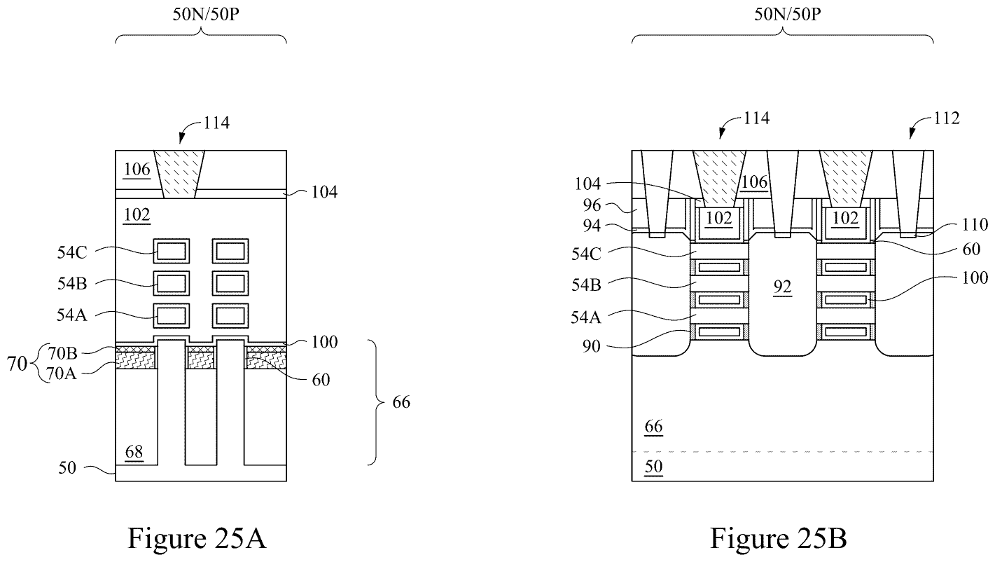

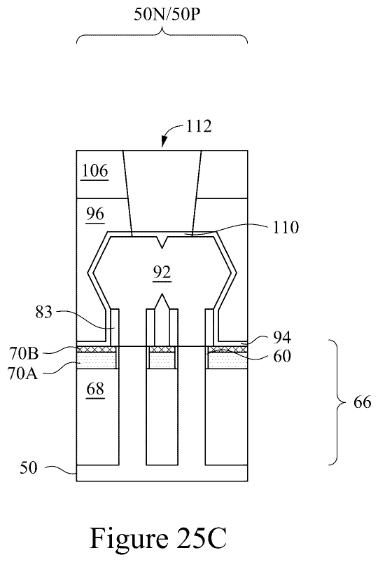

In FIGS. 23A-23C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 25A-25C) penetrate through the gate mask 104 to contact the top surface of the recessed gate electrodes 102.

As further illustrated by FIGS. 23A-23C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

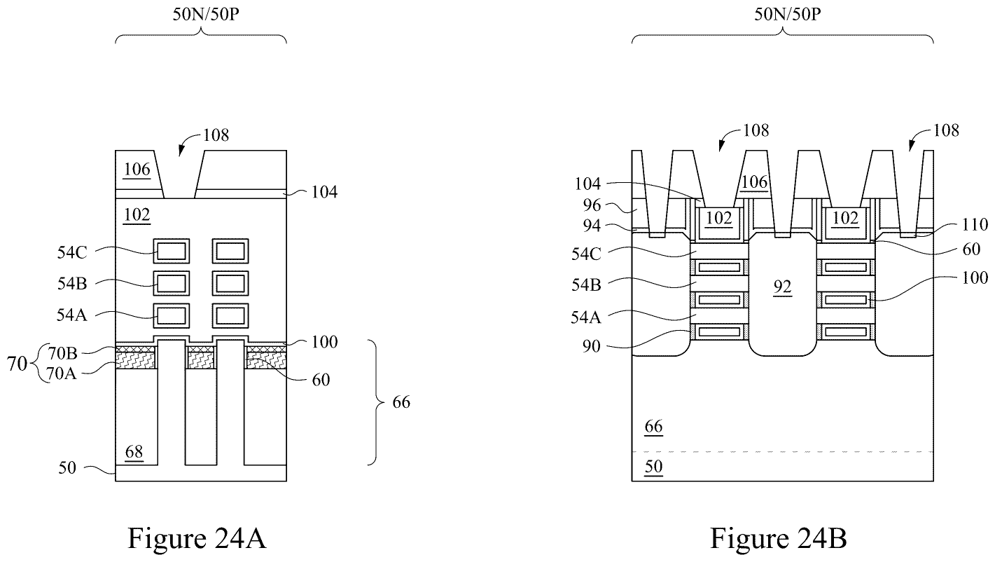

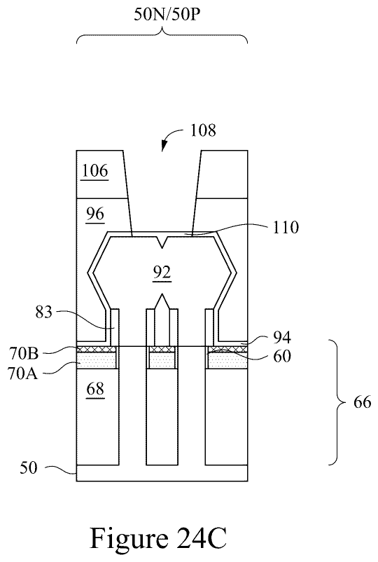

In FIGS. 24A-24C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 26B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 25A-25C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 26A-26B illustrate cross-sectional views of a device according to some alternative embodiments. FIG. 26A illustrates reference cross-section A-A′ illustrated in FIG. 1. FIG. 26B illustrates reference cross-section B-B′ illustrated in FIG. 1. FIG. 26C illustrates reference cross-section C-C′ illustrated in FIG. 1. In FIGS. 26A-26C, like reference numerals indicate like elements formed by like processes as the structure of FIGS. 25A-25C. For example, the structures of FIGS. 26A-26C includes bilayer hard mask structures 70 comprising a first and second hard masks 70A and 70B as described above. However, in FIGS. 26A-26C, the protective liner 60 does not remain on sidewalls of the fins 66, and the hard mask structures 70 may be in direct physical contact with the fins 66. For example, the protective liner 60 may not be formed or the protective liner 60 may be completely removed during one or more removal steps described above (e.g., dummy gate removal).

In various embodiments, isolation regions are formed between and around fins of a transistor to provide isolation between various active regions of the transistors. Protective liners may be formed to cover sidewalls, a bottom surface, and a top surface of the isolation region to reduce isolation loss during subsequent cleaning and/or etching processes that are performed to fabricate the transistors. The outer, protective liners may be nitride layers when the inner, isolation region is made of an oxide. In this manner, the protective liners can provide etch selectivity to the encapsulated isolation regions and reduce isolation loss (e.g., STI loss) during subsequently applied cleaning/etching processes. As a result, manufacturing defects can be reduced, and electrical performance of the resulting device can be improved.

In various embodiments, hard mask layers may be formed on a top surface of an isolation region to reduce isolation region loss during subsequent cleaning and/or etching processes that are performed to fabricate the transistor. The hard mask layers may include a nitride hard mask, and a silicon hard mask over the nitride hard mask. Due to the high etching selectivity of the silicon hard mask compared to even the nitride hard mask, the silicon hard mask may provide additional protection during the subsequent processing steps (e.g., etching steps). Thus, the combined thickness of the hard mask layers can be kept relatively low while still providing adequate protection to the underlying isolation region, and parasitic capacitance that result from overly thick hard mask layers can be reduced. The thinner hard mask layers further reduce the risk of unintentionally covering nanostructures in the transistor and impeding transistor performance. As a result, manufacturing defects can be reduced, and electrical performance of the resulting device can be improved.

In various embodiments, a device includes a first semiconductor fin and a second semiconductor fin; an isolation structure between the first semiconductor fin and the second semiconductor fin; a hard mask structure over the isolation structure, wherein the hard mask structure comprises a semiconductor hard mask covering the isolation structure; a plurality of nanostructures over the first semiconductor fin; and a gate structure over the hard mask structure and the first semiconductor fin, wherein the gate structure surrounds each of the plurality of nanostructures. Optionally, in some embodiments, the hard mask structure further comprises a nitride hard mask between the semiconductor hard mask and the isolation structure. Optionally, in some embodiments, a ratio of nitrogen to silicon of the nitride hard mask is in a range of 0.7 to 1.5. Optionally, in some embodiments, the semiconductor hard mask comprises silicon. Optionally, in some embodiments, a top surface of the hard mask structure is lower than a bottom surface of the plurality of nanostructures. Optionally in some embodiments, the semiconductor hard mask extends from the first semiconductor fin to the second semiconductor fin. Optionally in some embodiments, the semiconductor hard mask comprises a native oxide region at a top surface of the semiconductor hard mask.

In an embodiment, a device includes a semiconductor fin; a plurality of nanostructures over the semiconductor fin; first and second source/drain regions in the semiconductor fin, the plurality of nanostructures extending between the first and second source/drain regions; a shallow trench isolation (STI) region along a sidewall of the semiconductor fin; a first hard mask over the STI region, wherein the first hard mask comprises an insulating material; a second hard mask over the first hard mask, wherein the second hard mask comprises a semiconductor material; and a gate structure surrounding the plurality of nanostructures, the gate structure overlapping a first portion of the second hard mask. Optionally, in some embodiments, the first hard mask comprises a nitride, and wherein the second hard mask comprises silicon. Optionally, in some embodiments, a ratio of nitrogen to silicon of the first hard mask is in a range of 0.7 to 1.5. Optionally, in some embodiments, the device further includes a dielectric layer around the gate structure, the dielectric layer overlapping a second portion of the second hard mask. Optionally, in some embodiments, the first portion of the second hard mask has a first thickness, wherein the second portion of the second hard mask has a second thickness, and wherein the first thickness is less than the second thickness.

In an embodiment, a method includes etching a trench in a substrate to define a first semiconductor fin and a second semiconductor fin, the trench being disposed between a first semiconductor fin and a second semiconductor fin; forming a shallow trench isolation (STI) region in the trench; forming a first hard mask over the STI region; forming a second hard mask over the first hard mask, the second hard mask comprising a semiconductor material; and forming a gate structure over and along sidewalls of the first semiconductor fin, wherein the gate structure covers at least a portion of the second hard mask. Optionally, in some embodiments, the first hard mask comprises a nitride, and the second hard mask comprises silicon. Optionally, in some embodiments, the method further includes forming a protective liner over and along sidewalls of the first semiconductor fin and the second semiconductor fin after forming the STI region and before forming the first hard mask. Optionally, in some embodiments, forming the second hard mask comprises: depositing a second liner material over a top surface of the first semiconductor fin, over sidewalls of the first semiconductor fin, and over a top surface of the first hard mask; removing a first portion of the second liner material, the first portion of second liner layer being disposed over the top surface of the first semiconductor fin; and removing second portions of the second liner layer, the second portions of the second liner layer being disposed on sidewalls of the first semiconductor fin, wherein after removing the second portions of the second liner layer, a third portion of the second liner layer defines the second hard mask, the third portion of the second liner layer being disposed on a bottom surface of the trench. Optionally, in some embodiments, depositing the second liner material comprises a non-conformal deposition process that deposits the third portion of the second liner material to have a greater thickness than the first portion of the second liner material and the second portions of the second liner material, and wherein removing the first portion of the second liner material and removing the second portions of the second liner material comprise an isotropic etching process. Optionally, in some embodiments, depositing the second liner material comprises a flowable chemical vapor deposition (FCVD) process. Optionally, in some embodiments, a thickness of the second hard mask is in a range of 1 nm to 10 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first semiconductor fin and a second semiconductor fin;
an isolation structure between the first semiconductor fin and the second semiconductor fin;
a hard mask structure over the isolation structure, wherein the hard mask structure comprises a semiconductor hard mask covering the isolation structure;
a plurality of nanostructures over the first semiconductor fin; and
a gate structure over the hard mask structure and the first semiconductor fin, wherein the gate structure surrounds each of the plurality of nanostructures.

2. The device of claim 1, the hard mask structure further comprises a nitride hard mask between the semiconductor hard mask and the isolation structure.

3. The device of claim 2, wherein a ratio of nitrogen to silicon of the nitride hard mask is in a range of 0.7 to 1.5.

4. The device of claim 1, wherein the semiconductor hard mask comprises silicon.

5. The device of claim 1, wherein a top surface of the hard mask structure is lower than a bottom surface of the plurality of nanostructures.

6. The device of claim 1, wherein the semiconductor hard mask extends from the first semiconductor fin to the second semiconductor fin.

7. The device of claim 1, wherein the semiconductor hard mask comprises a native oxide region at a top surface of the semiconductor hard mask.

8. A device comprising:
a semiconductor fin;
a plurality of nanostructures over the semiconductor fin;
first and second source/drain regions in the semiconductor fin, the plurality of nanostructures extending between the first and second source/drain regions;
a shallow trench isolation (STI) region along a sidewall of the semiconductor fin;
a first hard mask over the STI region, wherein the first hard mask comprises an insulating material;
a second hard mask over the first hard mask, wherein the second hard mask comprises a semiconductor material; and
a gate structure surrounding the plurality of nanostructures, the gate structure overlapping a first portion of the second hard mask.

9. The device of claim 8, wherein the first hard mask comprises a nitride, and wherein the second hard mask comprises silicon.

10. The device of claim 9, wherein a ratio of nitrogen to silicon of the first hard mask is in a range of 0.7 to 1.5.

11. The device of claim 8, further comprising a dielectric layer around the gate structure, the dielectric layer overlapping a second portion of the second hard mask.

12. The device of claim 11, wherein the first portion of the second hard mask has a first thickness, wherein the second portion of the second hard mask has a second thickness, and wherein the first thickness is less than the second thickness.

13. The device of claim 8 further comprising a protective liner between the first hard mask and the STI region, wherein the protective liner comprises a semiconductor material.

14. A method comprising:
etching a trench in a substrate to define a first semiconductor fin and a second semiconductor fin, the trench being disposed between a first semiconductor fin and a second semiconductor fin;
forming a shallow trench isolation (STI) region in the trench;
forming a first hard mask over the STI region;
forming a second hard mask over the first hard mask, the second hard mask comprising a semiconductor material; and
forming a gate structure over and along sidewalls of the first semiconductor fin, wherein the gate structure covers at least a portion of the second hard mask.

15. The method of claim 14, wherein the first hard mask comprises a nitride, and the second hard mask comprises silicon.

16. The method of claim 14 further comprising forming a protective liner over and along sidewalls of the first semiconductor fin and the second semiconductor fin after forming the STI region and before forming the first hard mask.

17. The method of claim 14, wherein forming the second hard mask comprises:
depositing a second liner material over a top surface of the first semiconductor fin, over sidewalls of the first semiconductor fin, and over a top surface of the first hard mask;
removing a first portion of the second liner material, the first portion of second liner layer being disposed over the top surface of the first semiconductor fin; and
removing second portions of the second liner layer, the second portions of the second liner layer being disposed on sidewalls of the first semiconductor fin, wherein after removing the second portions of the second liner layer, a third portion of the second liner layer defines the second hard mask, the third portion of the second liner layer being disposed on a bottom surface of the trench.

18. The method of claim 17, wherein depositing the second liner material comprises a non-conformal deposition process that deposits the third portion of the second liner material to have a greater thickness than the first portion of the second liner material and the second portions of the second liner material, and wherein removing the first portion of the second liner material and removing the second portions of the second liner material comprise an isotropic etching process.

19. The method of claim 18, wherein depositing the second liner material comprises a flowable chemical vapor deposition (FCVD) process.

20. The method of claim 14, wherein a thickness of the second hard mask is in a range of 1 nm to 10 nm.
